(19) United States
(12) Patent Application Publication
(10) Pub. No.: US 2020/0182777 A1
(43) Pub. Date: Jun. 11, 2020

(54) SUBSTRATE INSPECTION APPARATUS, METHOD OF CALIBRATING THE SUBSTRATE INSPECTION APPARATUS, AND METHOD OF FABRICATING SEMICONDUCTOR DEVICE USING THE SAME

(71) Applicant: Samsung Electronics Co., Ltd., Suwon-si (KR)

(72) Inventors: Jang Ik PARK, Suwon-si (KR); Kwang Rak KIM, Gunpo-si (KR); Yoon Sung BAE, Seoul (KR); Young Hoon SOHN, Incheon (KR); Yu Sin YANG, Seoul (KR); Tae Yong JO, Hwaseong-si (KR)

(21) Appl. No.: 16/532,662

(22) Filed: Aug. 6, 2019

(30) Foreign Application Priority Data
Dec. 6, 2018 (KR) 10-2018-0155805

(51) Int. Cl. G01N 21/27; G01N 21/95; H01L 21/66

(52) U.S. Cl. CPC G01N 21/274; G01N 21/9501; G01N 2201/127; G01N 2201/0683; H01L 22/12

(57) ABSTRACT

A substrate inspection apparatus includes a light irradiating unit irradiating first light to an inspection target on a stage, a light detecting unit detecting second light reflected by the inspection target, a spectrum generator generating a first spectrum from the second light, a noise filter module removing a noise signal from the first spectrum to generate a second spectrum, a spectrum analyzer determining a first calibration parameter and a first calibration value thereof from the second spectrum, and a hardware controller adjusting at least one of the stage, the light irradiating unit and the light detecting unit using the first calibration parameter and the first calibration value.

This application claims priority under 35 U.S.C. § 119 to Korean Patent Application No. 10-2018-0155805, filed on Dec. 6, 2018 in the Korean Intellectual Property Office, the disclosure of which is incorporated herein in its entirety by reference.

### BACKGROUND

### 1. Field

The present disclosure relates to a substrate inspection apparatus, a method of calibrating the substrate inspection apparatus, and a method of fabricating a semiconductor device using the same.

### 2. Description of the Related Art

In the fabrication of semiconductor devices, a substrate inspection apparatus may be used to non-destructively measure and evaluate pattern formation or physical properties in real time. For example, the substrate inspection apparatus may be used to inspect or measure the thickness, line width, etc. of a material layer formed in a semiconductor fabrication process.

Here, a plurality of substrates on which the material layer is formed may be provided to a plurality of substrate inspection apparatuses to minimize time loss. In this case, however, there may be an error in inspection result value due to variance in measured values of the substrate inspection apparatuses.

To reduce the variance in the measured values of the substrate inspection apparatuses, calibration may be performed by matching inspection results of the substrate inspection apparatuses with each other. However, this can reduce the accuracy of the inspection results and time loss may increase as a number of substrate inspection apparatuses to be calibrated increases.

### SUMMARY

Aspects of the present disclosure provide a substrate inspection apparatus which can be easily calibrated in a minimized time.

Aspects of the present disclosure also provide a method of easily calibrating a substrate inspection apparatus in a minimized time.

Aspects of the present disclosure also provide a method of fabricating a semiconductor device using a substrate inspection apparatus which can be easily calibrated in a minimized time and a method of calibrating the substrate inspection apparatus.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an exemplary embodiment of the present inventive concept, a substrate inspection apparatus includes a stage on which an inspection target is loaded, a light irradiating unit which irradiates first light to the inspection target, a light detecting unit which detects second light reflected by the inspection target, a spectrum generator which generates a first spectrum from the second light, a noise filter module which removes a noise signal from the first spectrum to generate a second spectrum, a spectrum analyzer which determines a first calibration parameter and a first calibration value thereof from the second spectrum, and a hardware controller which adjusts at least one of the stage, the light irradiating unit and the light detecting unit using the first calibration parameter and the first calibration value.

According to an exemplary embodiment of the present inventive concept, a substrate inspection apparatus includes a stage on which an inspection target is loaded, a light irradiating unit which irradiates first light to the inspection target and comprises a polarizer, a light detecting unit which detects second light reflected by the inspection target and comprises an analyzer and a grating, and a computing device having a calibration library. The computing device receives information about the second light from the light detecting unit, determines a first calibration parameter from the calibration library using the information, and performs feedback control on at least one of the stage, the polarizer, the analyzer and the grating using the first calibration parameter. The calibration library includes the first calibration parameter of at least one of a tilt angle of the polarizer, a tilt angle of the grating, an incident angle of the first light, and a height of the stage.

According to an exemplary embodiment of the present inventive concept, a method of fabricating a semiconductor device is provided as follow. A substrate inspection apparatus is calibrated by irradiating first light to an inspection target, detecting second light reflected by the inspection target, generating a first spectrum using information about the second light, generating a second spectrum by filtering the first spectrum, comparing the second spectrum to a reference spectrum to generate a comparison result, determining a first calibration parameter and a first calibration value thereof using the comparison result and a calibration library and calibrating a hardware of the substrate inspection apparatus using the first calibration parameter and the first calibration value. A first material layer is formed on a substrate. The first material layer is inspected using the calibrated substrate inspection apparatus. The calibration library includes an entry of a relationship between the comparison result, and the first calibration parameter and the first calibration value. The comparison result includes a horizontal fluctuation of the second spectrum from the reference spectrum, a shift of the second spectrum from the reference spectrum, an offset of the second spectrum from the reference spectrum and a vertical fluctuation of the second spectrum from the reference spectrum. The first calibration parameter is associated with hardware of the substrate inspection apparatus in the calibration library.

According to an exemplary embodiment of the present inventive concept, a method of calibrating a substrate inspection apparatus is provided as follow. First light is irradiated to an inspection target. Second light reflected by the inspection target is detected. A detected spectrum is generated from the second light. The detected spectrum is compared to a reference spectrum to generate a comparison result. A first calibration parameter and a first calibration value thereof is determined from a calibration library using the comparison result. The substrate inspection apparatus is calibrated using the first calibration parameter and the first calibration value. The calibration library includes an entry of a relationship between the comparison result and the first calibration parameter.

### BRIEF DESCRIPTION OF THE DRAWINGS

These and/or other aspects will become apparent and more readily appreciated from the following description of the embodiments, taken in conjunction with the accompanying drawings in which:

FIG. 1 is a block diagram illustrating a method of fabricating a semiconductor device according to embodiments.

FIG. 2 is a block diagram of a substrate inspection apparatus according to embodiments.

FIG. 3 is a block diagram of the substrate inspection apparatus according to the embodiments.

FIG. 4 is a block diagram of a computing device according to embodiments.

FIGS. 5A and 5B are diagrams for explaining the operation of an equal spacer according to embodiments.

FIG. 6 illustrates a calibration library according to embodiments.

FIG. 7 illustrates a case where the error type of the second spectrum is a horizontal fluctuation according to embodiments.

FIG. 8 illustrates a case where the error type of the second spectrum is a shift according to embodiments.

FIG. 9 illustrates a case where the error type of the second spectrum is an offset according to embodiments.

FIG. 10 illustrates a case where the error type of the second spectrum is a vertical fluctuation according to embodiments.

FIG. 11 is a flowchart illustrating a method of calibrating a substrate inspection apparatus according to embodiments.

FIG. 12 is a flowchart illustrating a process of filtering a first spectrum according to embodiments.

FIG. 13 is a diagram for explaining a first spectrum according to embodiments.

FIG. 14 is a diagram for explaining a first transform spectrum and a second transform spectrum according to embodiments.

FIG. 15 is a diagram for explaining a third transform spectrum according to embodiments.

FIG. 16 is a diagram for explaining a second spectrum according to embodiments.

FIG. 17 is a flowchart illustrating a method of fabricating a semiconductor device using a substrate inspection apparatus calibrated using a method of calibrating a substrate inspection apparatus according to embodiments.

### DETAILED DESCRIPTION

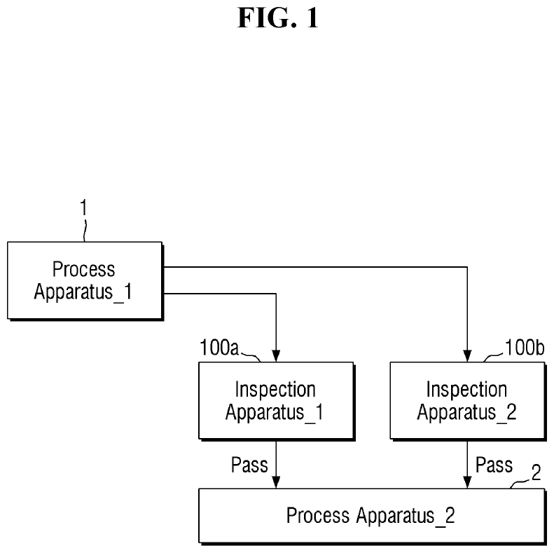

FIG. 1 is a block diagram illustrating a method of fabricating a semiconductor device according to embodiments.

Referring to FIG. 1, a semiconductor device may be fabricated on a substrate using a first process apparatus 1 and a second process apparatus 2. For example, each of the first process apparatus 1 and the second process apparatus 2 may include appropriate process equipment known in the semiconductor fabrication art, such as lithography equipment, etching equipment and deposition equipment.

The substrate may be made of a semiconductor material or a non-semiconductor material. A first material layer may be formed on the substrate using the first process apparatus 1. The first material layer may include, but is not limited to, a photoresist, a dielectric material, a conductive material, etc.

A plurality of substrates on which the first material layer is formed may be provided to a first substrate inspection apparatus 100a and a second substrate inspection apparatus 100b according to embodiments. For example, of N substrates, k substrates may be provided to the first substrate inspection apparatus 100a, and N-k substrates may be provided to the second substrate inspection apparatus 100b. In an example embodiment, each of the N substrates may be in a form of a wafer. The present concept is not limited thereto. In some embodiments, the substrates may be in a form of a rectangular or a square.

The first substrate inspection apparatus 100a and the second substrate inspection apparatus 100b may be the same apparatus. For example, the first substrate apparatus 100a and the second substrate inspection apparatus may include a spectroscopic reflectometer to measure a thickness of the first material layer if a conductive layer, a spectroscopic ellipsometer to measure a thickness of the first material layer if an insulating layer or an optical critical dimension (OCD) spectroscopy to measure a critical dimension of the first material layer, if patterned, such as a width of a patterned line and a spacing between two patterned lines. The first substrate inspection apparatus 100a and the second substrate inspection apparatus 100b may inspect a geometric feature of (e.g., thickness, critical dimension, shape, height, width, etc.) of the first material layer formed on the substrates or inspect characteristics such as the roughness of the first material layer on the substrates.

The substrates whose characteristics (i.e., the geometric feature) inspected by the first substrate inspection apparatus 100a and the second substrate inspection apparatus 100b are included in predetermined specifications may be provided to the second process apparatus 2 for subsequent processes. Here, since at least some of the substrates may be provided to different substrate inspection apparatuses (e.g., the first substrate inspection apparatus 100a and the second substrate inspection apparatus 100b) for inspection, the inspection performance of the first substrate inspection apparatus 100a and the inspection performance of the second substrate inspection apparatus 100b need to be matched with each other.

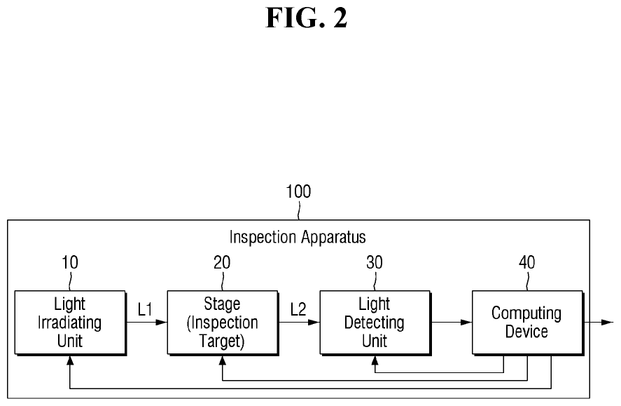

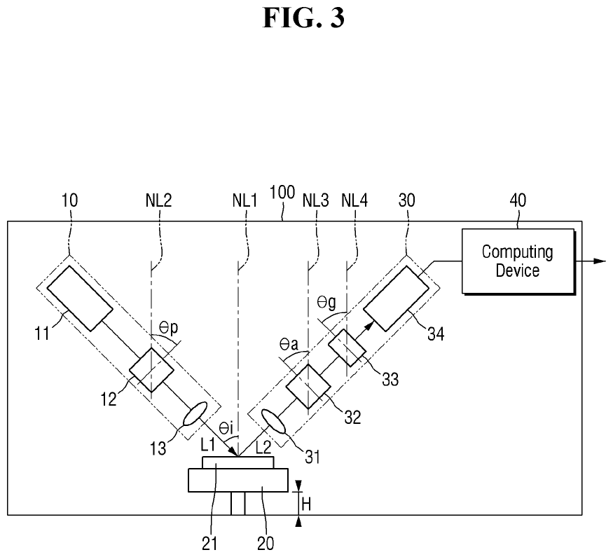

FIG. 2 is a block diagram of a substrate inspection apparatus 100 according to embodiments. FIG. 3 is a block diagram of the substrate inspection apparatus 100 according to the embodiments. Hereinafter, referring to FIGS. 2 and 3, the block diagram of the substrate inspection apparatus 100 will be described.

The substrate inspection apparatus 100 illustrated in FIG. 2 may be the first substrate inspection apparatus 100a and/or the second substrate inspection apparatus 100b illustrated in FIG. 1. The substrate inspection apparatus 100 includes a light irradiating unit 10, a stage 20, a light detecting unit 30, and a computing device 40. For example, the computing device 40 is disposed within the substrate inspection apparatus 100. However, this is merely for ease of description, and the computing device 40 may be implemented as an element located outside the substrate inspection apparatus 100. In this case, the light irradiating unit 10, the stage 20 and the light detecting unit 30 may be disposed within the substrate inspection apparatus 100 and the computing device 40 may be disposed outside the substrate inspection apparatus 100 and connected to the light detecting unit 30 therewithin.

The light irradiating unit 10 may generate first light L1. The first light L1 generated by the light irradiating unit 10 is provided to an inspection target 21 loaded on the stage 20. For example, the inspection target 21 may include a material layer to be inspected. The first light L1 is reflected by the inspection target 21 on the stage 20. The first light L1 reflected by the inspection target 21 is defined as second light L2. The second light L2 is provided to the light detecting unit 30. In other words, the light detecting unit 30 detects the second light L2 reflected by the inspection target 21. The light detecting unit 30 provides information about the second light L2 to the computing device 40. The computing device 40 may have at least two operation modes including a normal mode and a calibration mode. For the normal mode, the computing device 40 may inspect or calculate the geometric feature of the material layer of the inspection target 21 based on the information about the second light L2. For the calibration mode, the computing device 40 may determine a calibration parameter of the substrate inspection apparatus 100. The procedure of determining the calibration parameter will be described in detail. For a detailed description of the substrate inspection apparatus 100, reference is made to FIG. 3.

FIG. 3 is a block diagram of the substrate inspection apparatus 100 according to the embodiments. For ease of description, first through fourth normal lines NL1 through NL4 are defined. The first normal line NL1 is defined as a line perpendicular to an upper surface of the inspection target 21. The second normal line NL2, the third normal line NL3 and the fourth normal line NL4 are defined as lines parallel to the first normal line NL1 and pass through a polarizer 12, an analyzer 32, and a grating 33, respectively.

Referring to FIG. 3, the light irradiating unit 10 includes a light source 11, the polarizer 12, and a first lens 13. Light generated by the light source 11 is provided to the polarizer 12 and polarized. The polarizer 12 is tilted at a first angle θp with respect to the second normal line NL2. For example, the polarizer 12 may be tilted clockwise at the first angle θp with respect to the second normal line NL2. Light that passes through the polarizer 12 is provided to the first lens 13. The first lens 13 may refract the received light and irradiate the refracted light to the inspection target 21 as the first light L1. For example, the first lens 13 may focus the first light L1 on the material layer of the inspection target 21. The first light L1 is incident at a second angle θi with respect to the first normal line NL1 on the upper surface of the inspection target 21. In other words, the incident angle of the first light L1 is the second angle θi.

The inspection target 21 may be loaded on the stage 20. The stage 20 is positioned at a first height H from a lower surface of the substrate inspection apparatus 100.

The first light L1 irradiated to the inspection target 21 may be reflected by the inspection target 21 and provided to the light detecting unit 30 as the second light L2.

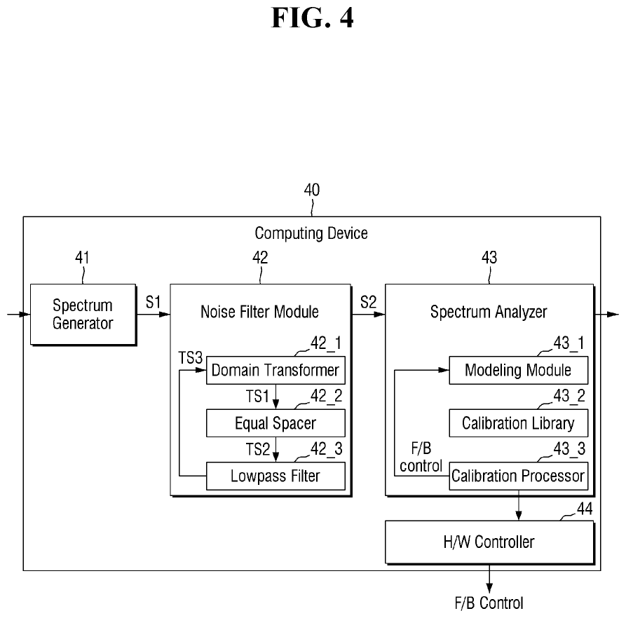

The light detecting unit 30 includes a second lens 31, the analyzer 32, the grating 33, and a photodetector 34. The second light L2 is provided to the second lens 31. The second lens 31 may refract the second light L2 and provide the refracted second light L2 to the analyzer 32. The analyzer 32 may be used to identify the degree of polarization of received light and the direction of a polarization plane of the received light. The analyzer 32 is tilted at a third angle θa with respect to the third normal line NL3. For example, the analyzer 32 may be tilted counter-clockwise at the third angle θa with respect to the third normal line NL3. Light that passes through the analyzer 32 is provided to the grating 33. The grating 33 may spectrally disperse the received light using diffraction of light. The grating 33 is tilted at a fourth angle θg with respect to the fourth normal line NL4. For example, the grating 33 may be tilted counter-clockwise at the fourth angle θg with respect to the fourth normal line NL4. The light spectrally dispersed by the grating 33 is provided to the photodetector 34. The photodetector 34 may be, for example, a charge-coupled device (CCD) camera or a complementary metal-oxide semiconductor (CMOS) camera. The photodetector 34 may convert a received optical signal into an electrical signal. In addition, the photodetector 34 may provide the electrical signal to the computing device 40. That is, the electrical signal provided by the photodetector 34 may include the information about the second light L2. The computing device 40 will now be described in detail with reference to FIG. 4.

FIG. 4 is a block diagram of a computing device 40 according to embodiments.

Referring to FIG. 4, the computing device 40 includes a spectrum generator 41, a noise filter module 42, a spectrum analyzer 43, and a hardware controller 44. Each of the spectrum generator 41, the noise filter module 42, the spectrum analyzer 43, and the hardware controller 44 may be implemented in software, firmware, hardware, or some suitable combination of at least two of the three.

The spectrum generator 41 generates a first spectrum S1 using an electrical signal provided by the light detecting unit 30, more specifically, by the photodetector 34 therein. The first spectrum S1 may be the result of plotting unprocessed raw data generated from the photodetector 34. For example, the first spectrum S1 of the second light L2 may contain information on how the optical energy or power (i.e., light intensity) is distributed over different wavelengths (i.e., a wavelength (λ) domain). The first spectrum S1 may include information on the geometric feature of the material layer and a noise signal, for example, generated by the photodetector 34. The spectrum generator 41 may provide the generated first spectrum S1 to the noise filter module 42. Those skilled in the art should be familiar with the uses and the configuration of the spectrum generator 41, and thus for the convenience of description, the specific exemplary configuration of the spectrum generator 41 is omitted.

The noise filter module 42 includes a domain transformer 42_1, an equal spacer 42_2, and a low-pass filter 42_3.

The domain transformer 42_1 may transform the domain of the received first spectrum S1. For example, the domain transformer 42_1 may transform the received first spectrum S1 from a wavelength (λ) domain into a wavenumber (1/λ) domain. The first spectrum S1 whose domain has been transformed is defined as a first transform spectrum TS1. The domain transformer 42_1 provides the first transform spectrum TS1 to the equal spacer 42_2.

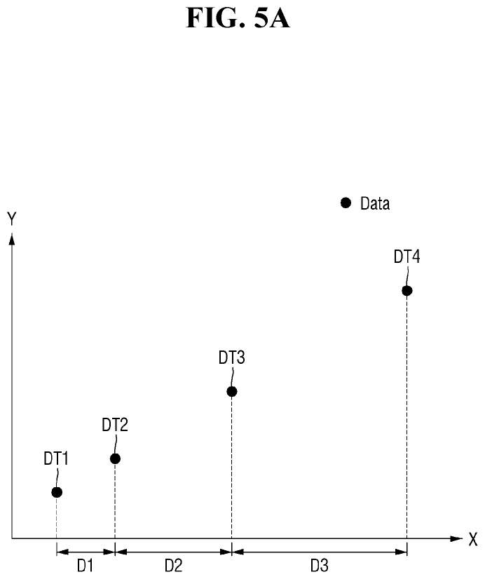

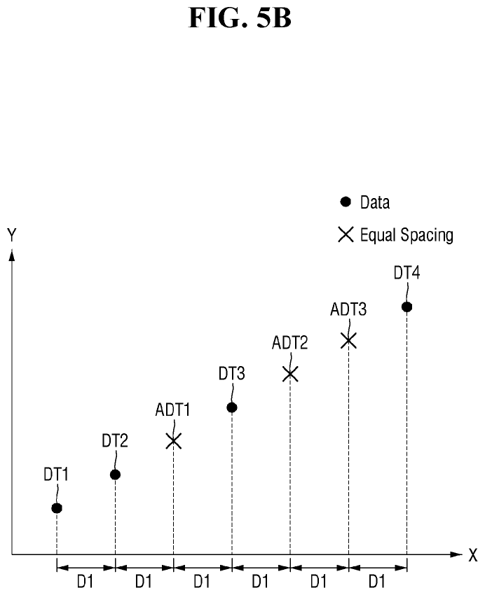

The equal spacer 42_2 may add specific data or dummy data to the data of the first transform spectrum TS1 to generate a second transform spectrum TS2 having wavenumbers that are arranged at an equal interval or substantially the same interval in an X direction (i.e., the wavenumber domain). For illustrative purposes, reference is made to FIGS. 5A and 5B to describe the operation of the equal spacer 42_2 in detail.

FIGS. 5A and 5B are diagrams for explaining the operation of the equal spacer 42_2 according to embodiments.

Referring to FIG. 5A, first through fourth data DT1 through DT4 are plotted. The first data DT1 and the second data DT2 are spaced apart by a first distance D1 in the X direction. In addition, the second data DT2 and the third data DT3 are spaced apart by a second distance D2 in the X direction. In addition, the third data DT3 and the fourth data DT4 are spaced apart by a third distance D3 in the X direction. The first through third distances D1 through D3 have different values. The equal spacer 42_2 may generate additional data based on the first through fourth data DT1 through DT4. For example, reference is made to FIG. 5B.

Referring to FIG. 5B, the equal spacer 42_2 may generate first additional data ADT1 between the second data DT2 and the third data DT3 and generate second additional data ADT2 and third additional data ADT3 between the third data DT3 and the fourth data DT4. Therefore, the first data DT1 and the second data DT2, the second data DT2 and the first additional data ADT1, the first additional data ADT1 and the third data DT3, the third data DT3 and the second additional data ADT2, the second additional data ADT2 and the third additional data ADT3, and the third additional data ADT3 and the fourth data DT4 are respectively spaced apart from each other by the same first distance D1 in the X direction. Here, Y values of the first through third additional data ADT1 through ADT3 may be determined based on the first through fourth data DT1 through DT4. For example, the equal spacer 42_2 may determine the Y values of the first through third additional data ADT1 through ADT3 based on a regression analysis of the first through fourth data DT1 through DT4. Although linear data are illustrated in FIGS. 5A and 5B for ease of description, embodiments are not limited to this case.

Referring again to FIG. 4, the equal spacer 42_2 generates the second transform spectrum TS2 by arranging the first transform spectrum TS1 at an equal interval or substantially the same interval. For example, the equal spacer 42_2 may insert dummy data in the first transform spectrum TS1 so that the second transform spectrum TS2 includes data distributed with an equal interval or substantially the same interval over the wavenumber domain. As described above, the distances between data included in the second transform spectrum TS2 may be equal or substantially the same in the X direction. The second transform spectrum TS2 generated by the equal spacer 42_2 is provided to the low-pass filter 42_3.

The low-pass filter 42_3 low-pass filters the second transform spectrum TS2. The second transform spectrum TS2 that passes through the low-pass filter 42_3 is provided to the domain transformer 42_1 as a third transform spectrum TS3. The low-pass filter 42_3 according to embodiments may be a zero-phase low-pass filter. In other words, the second transform spectrum TS2 and the third transform spectrum TS3 may have the same phase.

The domain transformer 42_1 transforms the third transform spectrum TS3 from the wavenumber (1/λ) domain back into the wavelength (λ) domain. The domain transformer 42_1 provides the third transform spectrum TS3, which has been transformed into the wavelength (λ) domain, to the spectrum analyzer 43 as a second spectrum S2.

The spectrum analyzer 43 receives the second spectrum S2. The spectrum analyzer 43 according to embodiments includes a modeling module 43_1, a calibration library 43_2, and a calibration processor 43_3. The spectrum analyzer 43 may be implemented in software, firmware, hardware, or some suitable combination of at least two of the three.

The modeling module 43_1 may generate a modeling spectrum. The modeling spectrum may be a spectrum generated using information on a material and a geometric feature of the expected structure. The geometric feature may include thickness and profile (i.e., shape) of an expected structure. The modeling module 43_1 may obtain the thickness and profile of the inspection target 21 by comparing the modeling spectrum and the second spectrum S2 and fitting the second spectrum S2 to the modeling spectrum. The modeling module 43_1 may output the thickness and profile of the inspection target 21 as an output of the substrate inspection apparatus 100.

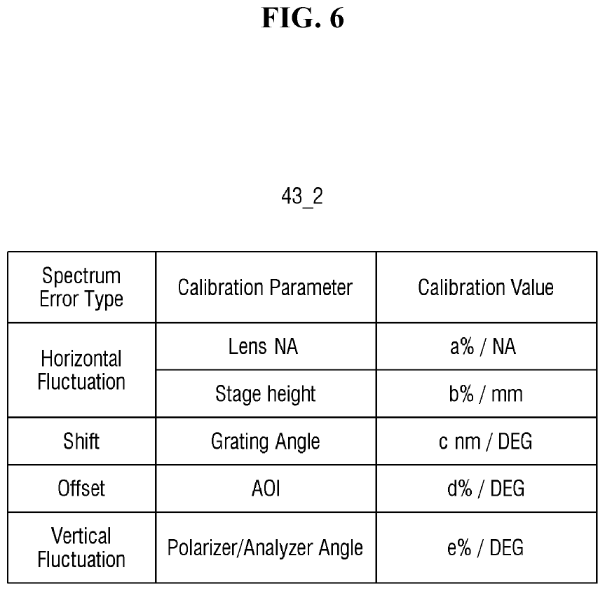

The calibration library 43_2 may include information about error types of the second spectrum S2, types of parameters that need to be calibrated, and calibration values. For illustrative purposes, reference is made to FIG. 6.

FIG. 6 illustrates the calibration library 43_2 according to embodiments.

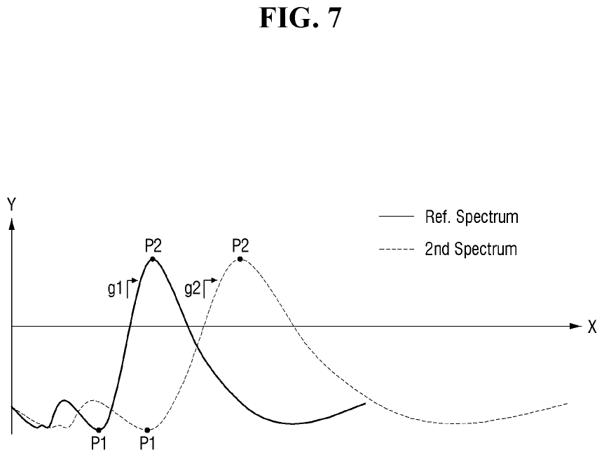

Referring to FIG. 6, the calibration library 43_2 includes error types of the second spectrum S2, parameters that need to be calibrated (calibration parameters), and calibration values of the calibration parameters. According to embodiments, the error types of the second spectrum S2 may include a horizontal fluctuation, a shift, an offset, and a vertical fluctuation. The error types of the second spectrum S2 will now be described with reference to FIGS. 7 through 10. In an example embodiment, the error types of the second spectrum S2 may be determined by the calibration processor 43_3 which will be described in detail.

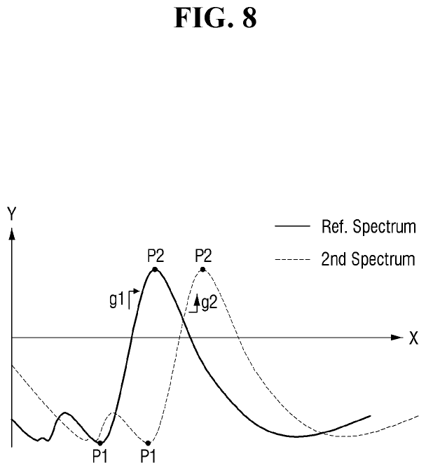

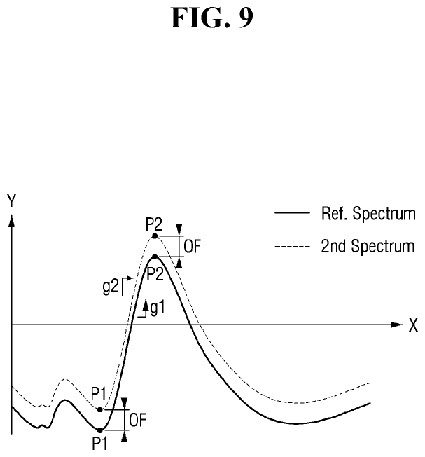

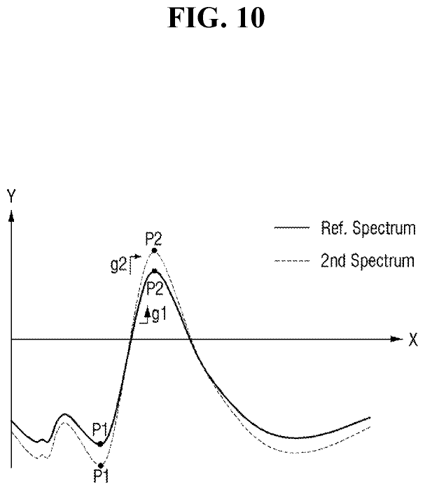

FIG. 7 illustrates a case where the error type of the second spectrum S2 is a horizontal fluctuation according to embodiments. FIG. 8 illustrates a case where the error type of the second spectrum S2 is a shift according to embodiments. FIG. 9 illustrates a case where the error type of the second spectrum S2 is an offset according to embodiments. FIG. 10 illustrates a case where the error type of the second spectrum is a vertical fluctuation according to embodiments. For example, FIGS. 7 to 10 show comparison results between the second spectrum S2 and a reference spectrum. In an example embodiment, the reference spectrum may be prepared with samples of which geometric features are known. The comparison results may be obtained by the calibration processor 43_3. In an example embodiment, the calibration processor 43_3 may identify one of the comparison results as shown in FIGS. 7 to 10 and search the calibration library 43_2 using the identified comparison result to select a calibration type and a calibration value thereof. The comparison results of the present invention are not limited to the comparison results of the FIGS. 7 to 10. Depending on the complexity of the substrate inspection apparatus 100, a number of the comparison results may be less or more than discussed with reference to FIGS. 7 to 10.

For ease of description, a highest point and a lowest point of each spectrum are indicated by P1 and P2, respectively. Referring to FIG. 7, when the error type of the second spectrum S2 is a horizontal fluctuation, the second spectrum S2 is expanded or reduced in the X direction as compared to the reference spectrum. For example, FIG. 7 shows a horizontal fluctuation of the second spectrum S2 from the reference spectrum. In this case, the comparison result (i.e., the error type of the second spectrum S2) may be identified as the horizontal fluctuation. Here, the size of the highest point P2 of the reference spectrum in a Y direction may be equal to the size of the highest point P2 of the second spectrum S2 in the Y direction. However, the position of the highest point P2 of the reference spectrum in the X direction may be different from the position of the highest point P2 of the second spectrum S2 in the X direction. Likewise, the position of the lowest point P1 of the reference spectrum in the X direction may be different from the position of the lowest point P1 of the second spectrum S2 in the X direction. In addition, a first gradient g1 from the lowest point P1 to the highest point P2 of the reference spectrum may be different from a second gradient g2 from the lowest point P1 to the highest point P2 of the second spectrum S2. For example, the first gradient g1 may be larger or smaller than the second gradient g2. Although the first gradient g1 is larger than the second gradient g2 in FIG. 7, embodiments are not limited to this case. In addition, the second spectrum S2 is expanded in a +X direction as compared to the reference spectrum in FIG. 7, embodiments are not limited to this case. For example, the second spectrum S2 may also be expanded (or reduced) in a −X direction or in both the +X and −X directions as compared to the reference spectrum.

Referring to FIG. 8, when the error type of the second spectrum S2 is a shift, the second spectrum S2 may be shifted in the X direction from the reference spectrum. For example, FIG. 8 shows a shift of the second spectrum S2 from the reference spectrum. In this case, the comparison result (i.e., the error type of the second spectrum S2) may be identified as the shift. When the error type of the second spectrum S2 is the shift, the highest point P2 of the reference spectrum and the highest point P2 of the second spectrum S2 have the same size in the Y direction. In addition, the first gradient g1 from the lowest point P1 to the highest point P2 of the reference spectrum may be equal to the second gradient g2 from the lowest point P1 to the highest point P2 of the second spectrum S2. However, the position of the highest point P2 of the reference spectrum in the X direction may be different from the position of the highest point P2 of the second spectrum S2 in the X direction. Likewise, the position of the lowest point P1 of the reference spectrum in the X direction may be different from the position of the lowest point P1 of the second spectrum S2 in the X direction. Although the second spectrum S2 has been shifted in the +X direction from the reference spectrum in FIG. 8, embodiments are not limited to this case. For example, the second spectrum S2 may also be shifted in the −X direction from the reference spectrum.

Referring to FIG. 9, when the error type of the second spectrum S2 is an offset, the second spectrum S2 may be shifted in the Y direction from the reference spectrum. For example, FIG. 9 shows an offset of the second spectrum S2 from the reference spectrum. In this case, the comparison result (i.e., the error type of the second spectrum S2) may be identified as the offset. When the error type of the second spectrum S2 is the offset, the reference spectrum and the second spectrum S2 have the highest point P2 and the lowest point P1 at the same position in the X direction. In addition, the first gradient g1 from the lowest point P1 to the highest point P2 of the reference spectrum may be equal to the second gradient g2 from the lowest point P1 to the highest point P2 of the second spectrum S2. However, the sizes of the highest point P2 and the lowest point P1 of the second spectrum S2 in the Y direction may respectively be different from those of the highest point P2 and the lowest point P1 of the reference spectrum in the Y direction by an offset value OF. Although the second spectrum S2 has been shifted in a +Y direction from the reference spectrum in FIG. 9, embodiments are not limited to this case. For example, the second spectrum S2 may also be shifted in a −Y direction from the reference spectrum.

Referring to FIG. 10, when the error type of the second spectrum S2 is a vertical fluctuation, the second spectrum S2 may be expanded or reduced in the Y direction as compared to the reference spectrum. For example, FIG. 10 shows a vertical fluctuation of the second spectrum S2 from the reference spectrum. In this case, the comparison result (i.e., the error type of the second spectrum S2) may be identified as the vertical fluctuation. When the error type of the second spectrum S2 is the vertical fluctuation, the reference spectrum and the second spectrum S2 have the highest point P2 and the lowest point P1 at the same position in the X direction. On the other hand, the sizes of the highest point P2 and the lowest point P1 of the reference spectrum in the Y direction may be different from those of the highest point P2 and the lowest point P1 of the second spectrum S2 in the Y direction. In addition, the first gradient g1 from the lowest point P1 to the highest point P2 of the reference spectrum may be different from the second gradient g2 from the lowest point P1 to the highest point P2 of the second spectrum S2. For example, the first gradient g1 may be larger or smaller than the second gradient g2. Although the first gradient g1 is smaller than the second gradient g2 in FIG. 10, embodiments are not limited to this case. In other words, although the second spectrum S2 is expanded in the Y direction as compared to the reference spectrum in FIG. 10, embodiments are not limited to this case. For example, the second spectrum S2 may also be reduced in the Y direction as compared to the reference spectrum.

In FIGS. 7 through 10, cases where the second spectrum S2 has the horizontal fluctuation, the shift, the offset, and the vertical fluctuation separately are respectively illustrated for ease of description. However, embodiments are not limited to this case, and the second spectrum S2 may also have a combination of at least two of the horizontal fluctuation, the shift, the offset, and the vertical fluctuation.

Referring again to FIG. 6, the calibration library 43_2 may include a calibration parameter and a calibration value corresponding to the error type of the second spectrum S2 (i.e., the comparison result of the second spectrum S2 and the reference spectrum).

According to some embodiments, when the error type of the second spectrum S2 is the horizontal fluctuation, a numerical aperture of a lens (e.g., the first lens 13 and/or the second lens 31) or the first height H of the stage 20 may be adjusted. For example, when the second spectrum S2 is enlarged or reduced by a % in a horizontal direction (e.g., the X direction) from the reference spectrum, the numerical aperture of the lens may be calibrated by increasing or reducing the numerical aperture by 1 NA per the a % of the horizontal fluctuation of the second spectrum S2 from the reference spectrum. In addition, when the error type of the second spectrum S2 is the horizontal fluctuation, the first height H of the stage 20 may be adjusted. For example, when the second spectrum S2 is expanded or reduced in the horizontal direction by b %, the first height H of the stage may be calibrated by increasing or reducing the first height H1 by 1 mm per the b % of the horizontal fluctuation of the second spectrum S2 from the reference spectrum.

According to some embodiments, when the error type of the second spectrum S2 is the shift, the fourth angle θg of the grating 33 may be adjusted. For example, when the second spectrum S2 is shifted in the horizontal direction by c nm, the fourth angle θg of the grating 33 may be calibrated by increasing or reducing the fourth angle θg by 1 degree per the c nm of the shift of the second spectrum S2 from the reference spectrum.

According to some embodiments, when the error type of the second spectrum S2 is the offset, the incident angle θi of the first light L1 may be adjusted. For example, when the second spectrum S2 is shifted in a vertical direction by d %, the second angle θi may be calibrated by increasing or reducing the incident angle θi by 1 degree per the d % of the shift of the second spectrum S2 from the reference spectrum. For example, the incident angle of the first light L1 may be adjusted by changing the angle of the light irradiating unit 10 or adjusting a part (e.g., a reflection mirror) in the light source 11.

According to some embodiments, when the error type of the second spectrum S2 is the vertical fluctuation, the angles (i.e., the first angle θp and the third angle θa) of the polarizer 12 and the analyzer 32 may be adjusted. For example, when the second spectrum S2 is shifted in the vertical direction by e %, the first angle θp and the third angle θa may be calibrated by increasing or reducing by 1 degree per the e % of the vertical fluctuation of the second spectrum from the reference spec.

Referring again to FIG. 4, the calibration processor 43_3 may determine a first calibration parameter and a first calibration value using the second spectrum S2 and the calibration library 43_2. For example, the calibration processor 43_3 may determine the error type of the second spectrum S2 by comparing the second spectrum S2 and the reference spectrum. The calibration processor 43_3 may determine the first calibration parameter and the first calibration value corresponding to the error type of the second spectrum S2 by referring to the calibration library 43_2. According to some embodiments, the first calibration parameter may include the numerical apertures of the first lens 13 and the second lens 31, the first height H of the stage 20, the fourth angle θg of the grating 33, the second angle θi (i.e., incident angle) of the first light L1, and the first angle θp and the third angle θa of the polarizer 12 and the analyzer 32. The calibration processor 43_3 may provide the determined first calibration parameter and first calibration value to the hardware controller 44 or the modeling module 43_1.

According to some embodiments, the hardware controller 44 may perform feedback control by adjusting at least one of the light irradiating unit 10, the stage 20 and the light detecting unit 30 based on the first calibration parameter and the first calibration value. For example, the hardware controller 44 may adjust at least one of the first height H of the stage 20, the fourth angle θg of the grating 33, the second angle θi (i.e., incident angle) of the first light L1, and the first angle θp and the third angle θa of the polarizer 12 and the analyzer 32 based on the first calibration parameter and the first calibration value.

According to some embodiments, the calibration processor 43_3 may perform feedback control by providing the first calibration parameter and the first calibration value to the modeling module 43_1. The modeling module 43_1 may calibrate the modeling spectrum based on the first calibration parameter and the first calibration value. The modeling module 43_1 may obtain the thickness and profile of the inspection target 21 by comparing the calibrated modeling spectrum and the second spectrum S2 and fitting the second spectrum S2 to the calibrated modeling spectrum.

According to some embodiments, the first calibration parameter and the first calibration value determined by the calibration processor 43_3 are provided to the hardware controller 44 or the modeling module 43_1. Alternatively, the calibration processor 43_3 may determine the first calibration parameter and the first calibration value and output the first calibration parameter and the first calibration value to the outside. A user may directly adjust at least one of the light irradiating unit 10, the stage 20 and the light detecting unit 30 by using the first calibration parameter and first calibration value.

In addition, although the modeling module 43_1, the calibration library 43_2 and the calibration processor 43_3 are all included in the spectrum analyzer 43 in FIG. 4, embodiments are not limited to this case. For example, at least some of the modeling module 43_1, the calibration library 43_2 and the calibration processor 43_3 may be implemented as a module (or modules) independent of the spectrum analyzer 43.

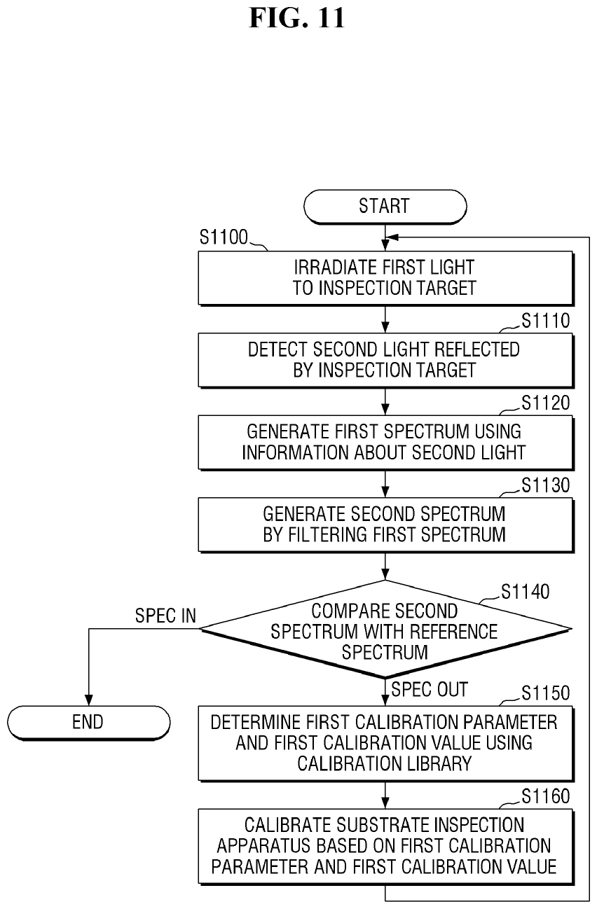

FIG. 11 is a flowchart illustrating a method of calibrating a substrate inspection apparatus 100 according to embodiments. For ease of description, descriptions of elements and features identical or similar to those described above will be omitted or given briefly.

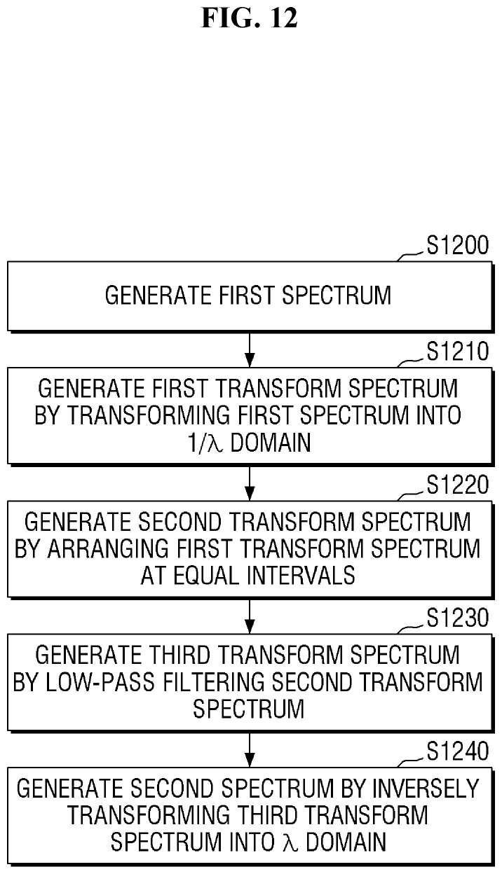

Referring to FIGS. 2, 3, 4 and 11, a light irradiating unit 10 irradiates first light L1 to an inspection target 21 loaded on a stage 20 (operation S1100). A light detecting unit 30 detects second light L2 reflected by the inspection target 21 (operation S1110). The light detecting unit 30 may provide information about the detected second light L2 to a computing device 40. The computing device 40 generates a first spectrum S1 by receiving the information about the second light L2 from the light detecting unit 30 (operation S1120). The computing device 40 generates a second spectrum S2 by filtering the first spectrum S1 (operation S1130). The process of filtering the first spectrum S1 will now be described with reference to FIGS. 12 through 16.

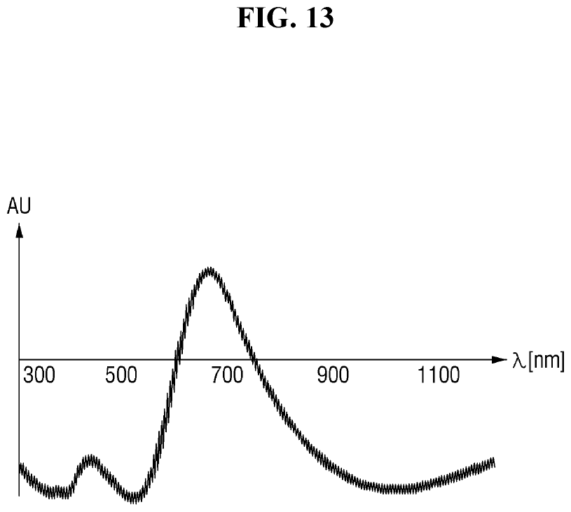

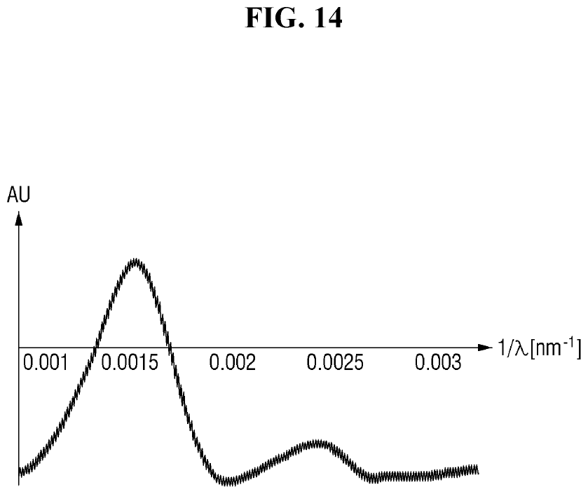

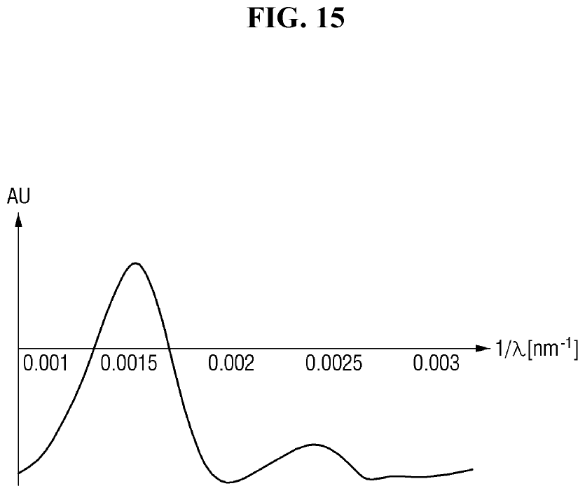

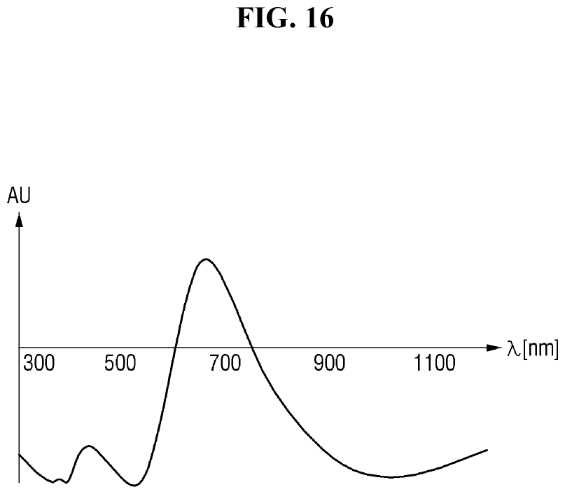

FIG. 12 is a flowchart illustrating a process of filtering the first spectrum S1 according to embodiments. FIG. 13 is a diagram for explaining the first spectrum S1 according to embodiments. FIG. 14 is a diagram for explaining the first transform spectrum TS1 and the second transform spectrum TS2 according to embodiments. FIG. 15 is a diagram for explaining a third transform spectrum TS3 according to embodiments. FIG. 16 is a diagram for explaining the second spectrum S2 according to embodiments. For ease of description, descriptions of elements and features identical or similar to those described above will be omitted or given briefly.

Referring to FIGS. 4 and 12, the spectrum generator 41 included in the computing device 40 generates the first spectrum S1 by using the information about the second light L2. For example, referring to FIG. 13, the generated first spectrum S1 may be data having a wavelength (λ) domain. For example, the first spectrum S1 of the second light L2 may contain information on how the optical energy or power (i.e., light intensity) is distributed over different wavelengths (i.e., the wavelength (λ) domain). The first spectrum S1 may contain noise. For example, the noise may be originated from the photodetector 34. Although the noise is exaggerated in FIG. 13 for ease of description, embodiments are not limited to this form of noise. The generated first spectrum S1 is provided to the domain transformer 42_1.

The domain transformer 42_1 generates the first transform spectrum TS1 by transforming the first spectrum S1 of the wavelength (λ) domain into a wavenumber (1/λ) domain (operation S1210). The equal spacer 42_2 generates the second transform spectrum TS2 by inserting dummy data in the first transform spectrum TS1 so that the second transform spectrum TS2 includes values at wavenumbers distributed at an equal interval or substantially the same interval. The spectrums illustrated in FIGS. 14 and 15 may show forms of the first transform spectrum TS1 and the second transform spectrum TS2, respectively. The first transform spectrum TS1 and the second transform spectrum TS2, as shown in FIGS. 14 and 15, may still contain the noise. The second transform spectrum TS2 is provided to a low-pass filter 42_3.

The low-pass filter 42_3 generates the third transform spectrum TS3 by low-pass filtering the second transform spectrum TS2 (operation S1230). For example, referring to FIG. 15, the third transform spectrum TS3 is without the noise. The third transform spectrum TS3 is provided to the domain transformer 42_1 again.

The domain transformer 42_1 inversely transforms the third transform spectrum TS3 of the wavenumber (1/λ) domain into the second spectrum S2 of the wavelength (λ) domain (operation S1240). For example, referring to FIGS. 13 and 16, the second spectrum S2 is the first spectrum S1 from which the noise thereof has been removed.

Referring to FIGS. 13 through 16, the peak (or wiggling) of the first spectrum S1 of the wavelength (λ) domain may be difficult to locate due to the noise from FIGS. 13 and 14. Data around the peak may be generally significant data for estimating the profile or geometric features of a material layer. If noise filtering is performed on the first spectrum S1 of the wavelength (λ) domain, the significant data may be filtered out and removed with the noise. On the other hand, the peak of the first transform spectrum TS1 of the wavenumber (1/λ) domain may be clearer than that of the first spectrum S1. Therefore, noise filtering may be performed not on the first spectrum S1 of the wavelength (λ) domain but on the second transform spectrum TS2 of the wavenumber (1/λ) domain to avoid the loss of the significant data around the peak.

Referring again to FIGS. 2, 4 and 11, the calibration processor 43_3 may compare the second spectrum S2 with the reference spectrum (operation S1140). When the comparison result indicates that the second spectrum S2 is similar to the reference spectrum or satisfies predetermined specifications, the calibration of the substrate inspection apparatus 100 is terminated.

When the result of comparing the second spectrum S2 with the reference spectrum using the calibration processor 43_3 does not satisfy the predetermined specifications, the calibration processor 43_3 determines a first calibration parameter and a first calibration value of the substrate inspection apparatus 100 by using the second spectrum S2 and the calibration library 43_2 (operation S1150). For example, the calibration processor 43_3 may determine the error type and the degree of error of the substrate inspection apparatus 100 by comparing the second spectrum S2 to the reference spectrum and determine the first calibration parameter and the first calibration value by using the calibration library 43_2.

Based on the determined first calibration parameter and first calibration value, the substrate inspection apparatus 100 may be calibrated. For example, the calibration processor 43_3 may provide the first calibration parameter and the first calibration value to the hardware controller 44, and the hardware controller 44 may adjust at least one of the light irradiating unit 10, the stage 20 and the light detecting unit 30. For another example, the calibration processor 43_3 may provide the first calibration parameter and the first calibration value to the modeling module 43_1, and the modeling module 43_1 may calibrate a modeling spectrum based on the first calibration parameter and the first calibration value. For another example, the calibration processor 43_3 may output the first calibration parameter and the first calibration value, and a user may adjust at least one of the light irradiating unit 10, the stage 20 and the light detecting unit 30 based on the first calibration parameter and the first calibration value.

In the method of calibrating the substrate inspection apparatus 100 according to the embodiments, result values of a first substrate inspection apparatus 100a and a second substrate inspection apparatus 100b are not matched with each other. Instead, an error factor of hardware included in each of the first substrate inspection apparatus 100a and the second substrate inspection apparatus 100b is obtained, and each of the first substrate inspection apparatus 100a and the second substrate inspection apparatus 100b is calibrated using the error factor. Therefore, the method of calibrating the substrate inspection apparatus 100 according to the embodiments is simpler and more accurate than the method of matching result values. Accordingly, calibration may be performed with minimized time loss and increased accuracy.

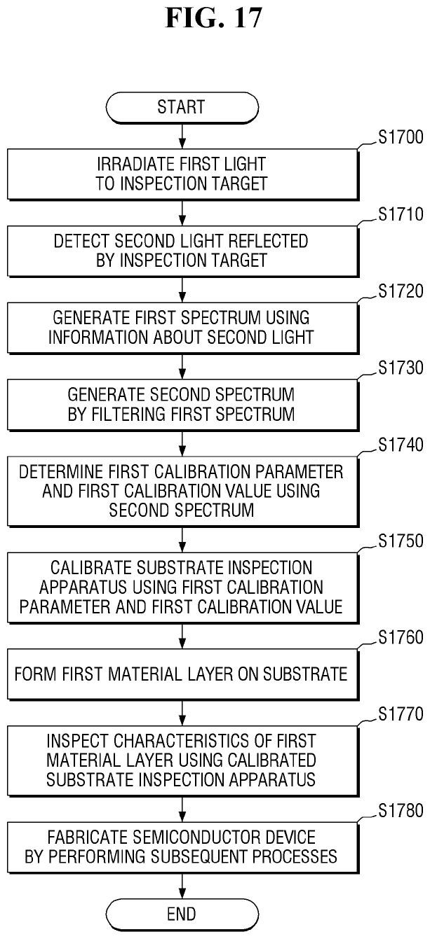

FIG. 17 is a flowchart illustrating a method of fabricating a semiconductor device using a substrate inspection apparatus calibrated using a method of calibrating a substrate inspection apparatus according to embodiments. For ease of description, descriptions of elements and features identical or similar to those described above will be omitted or given briefly.

Referring to FIGS. 2, 4 and 17, the light irradiating unit 10 irradiates the first light L1 to the inspection target 21 (operation S1700). The light detecting unit 30 detects the second light L2 reflected by the inspection target 21 (operation S1710). The computing device 40 generates the first spectrum S1 by using information about the second light L2 and generates the second spectrum S2 by filtering the first spectrum S1 (operations S1720 and S1730). In addition, the computing device 40 determines the first calibration parameter and the first calibration value by using the second spectrum S2 (operation S1740). Then, the substrate inspection apparatus 100 is calibrated using the first calibration parameter and the first calibration value, and the calibrated substrate inspection apparatus 100 is prepared (operation S1750).

A first material layer is formed on a substrate (operation S1760). The first material layer may include, but is not limited to, a photoresist, a dielectric material, a conductive material, etc.

The characteristics of the first material layer formed on the substrate are inspected using the calibration substrate inspection apparatus 100 (operation S1770). When the characteristics of the first material layer fall in the allowable criteria specified in predetermined specifications, subsequent processes are performed to fabricate a semiconductor device (operation S1780).

In concluding the detailed description, those skilled in the art will appreciate that many variations and modifications may be made to the exemplary embodiments without departing from the spirit and scope of the present inventive concept. Therefore, the disclosed preferred exemplary embodiments of the present inventive concept are used in a generic and descriptive sense only and not for purposes of limitation

1. A substrate inspection apparatus comprising:
a stage on which an inspection target is loaded;
a light irradiating unit which irradiates first light to the inspection target;
a light detecting unit which detects second light reflected by the inspection target;
a spectrum generator which generates a first spectrum from the second light;
a noise filter module which removes a noise signal from the first spectrum to generate a second spectrum;
a spectrum analyzer which determines a first calibration parameter and a first calibration value thereof from the second spectrum; and
a hardware controller which adjusts at least one of the stage, the light irradiating unit and the light detecting unit using the first calibration parameter and the first calibration value.

2. The apparatus of claim 1,
wherein the light irradiating unit comprises a light source, a polarizer and a first lens, and the light detecting unit comprises a second lens, an analyzer, a grating and a photodetector.

3. The apparatus of claim 2,
wherein the first calibration parameter comprises a tilt angle of the polarizer, a tilt angle of the grating, an incident angle of the first light, and a height of the stage.

4. The apparatus of claim 2,
wherein the hardware controller adjusts at least one of a tilt angle of the polarizer, a tilt angle of the grating, an incident angle of the first light, and a height of the stage using the first calibration parameter and the first calibration value.

5. The apparatus of claim 1,
wherein the noise filter module comprises a domain transformer, an equal spacer, and a low-pass filter.

6. The apparatus of claim 5,
wherein the domain transformer generates a first transform spectrum by transforming the first spectrum of a wavelength domain into a wavenumber domain,
the equal spacer generates a second transform spectrum by inserting at least one dummy value in the first transform spectrum so that wavenumbers of the second transform spectrum with the at least one dummy value are distributed at an equal interval in the wavenumber domain, and
the low-pass filter generates a third transform spectrum by low-pass filtering the second transform spectrum.

7. The apparatus of claim 6,
wherein the domain transformer receives the third transform spectrum and generates the second spectrum by inversely transforming the third transform spectrum into the wavelength domain.

8. (canceled)

9. The apparatus of claim 1,
wherein the spectrum analyzer compares the second spectrum to a reference spectrum and generates a comparison result.

10. The apparatus of claim 9,
wherein the spectrum analyzer determines the first calibration parameter and the first calibration value by using a calibration library having an entry in which the comparison result is associated with the first calibration parameter and the first calibration value.

11. The apparatus of claim 2,
wherein the spectrum analyzer compares the second spectrum to a reference spectrum to generate a comparison result, and
wherein the spectrum analyzer determines the first calibration parameter to be at least one of a height of the stage, a tilt angle of the grating, an incident angle of the first light and a tilt angle of the polarizer according to the comparison result.

12. The apparatus of claim 11, wherein the spectrum analyzer determines the first calibration parameter to be:
when the comparison result is a horizontal fluctuation of the second spectrum from the reference spectrum, the height of the stage;
when the comparison result is a shift of the second spectrum from the reference spectrum, the tilt angle of the grating;
when the comparison result is an offset of the second spectrum from the reference spectrum, the incident angle of the first light; and
when the comparison result is a vertical fluctuation of the second spectrum from the reference spectrum, the tilt angle of the polarizer.

13. The apparatus of claim 11,
wherein the hardware controller adjusts:
when the comparison result is a horizontal fluctuation of the second spectrum from the first spectrum, the height of the stage by the first calibration value;
when the comparison result is a shift of the second spectrum from the first spectrum, the tilt angle of the grating by the first calibration value;
when the comparison result is an offset of the second spectrum from the first spectrum, the incident angle of the first light by the first calibration value; and
when the comparison result is a vertical fluctuation of the second spectrum from the first spectrum, the tilt angle of the polarizer by the first calibration value.

14. A substrate inspection apparatus comprising:
a stage on which an inspection target is loaded;
a light irradiating unit which irradiates first light to the inspection target and comprises a polarizer;
a light detecting unit which detects second light reflected by the inspection target and comprises an analyzer and a grating; and
a computing device having a calibration library, the computing device configured to:
receive information about the second light from the light detecting unit;
determine a first calibration parameter from the calibration library using the information; and
perform feedback control on at least one of the stage, the polarizer, the analyzer and the grating using the first calibration parameter,
wherein the calibration library comprises the first calibration parameter of at least one of a tilt angle of the polarizer, a tilt angle of the grating, an incident angle of the first light, and a height of the stage.

15. The apparatus of claim 14,
wherein the computing device is further configured to:
generate a spectrum from the information;
generate a comparison result by comparing the spectrum to a reference spectrum; and determine the first calibration parameter using the comparison result.

16. The apparatus of claim 15,
wherein the comparison result comprises a horizontal fluctuation of the spectrum from the reference spectrum, a shift of the spectrum from the reference spectrum, an offset of the spectrum from the reference spectrum, or a vertical fluctuation of the spectrum from the reference spectrum.

17. The apparatus of claim 16,
wherein the computing device accesses the calibration library and determines as the first calibration parameter:
when the comparison result is the horizontal fluctuation, the height of the stage;
when the comparison result is the shift, the tilt angle of the grating;
when the comparison result is the offset, the incident angle of the first light; and
when the comparison result is the vertical fluctuation, the tilt angle of the polarizer.

18. The apparatus of claim 14,
wherein the computing device further generates a first spectrum using the information about the second light and generates a second spectrum by filtering the first spectrum.

19. The apparatus of claim 18,
wherein the computing device is further configured to:
generate a first transform spectrum by transforming the first spectrum of a wavelength domain into a wavenumber domain;
generate a second transform spectrum by inserting at least one dummy value in the first transform spectrum so that wavenumbers of the second transform spectrum with the at least one dummy value are distributed at an equal interval in the wavenumber domain;
generate a third transform spectrum by low-pass filtering the second transform spectrum; and
generate the second spectrum by inversely transforming the third transform spectrum into the wavelength domain.

20. A method of fabricating a semiconductor device, the method comprising:
calibrating a substrate inspection apparatus,
wherein the calibrating of the substrate inspection apparatus includes:
irradiating first light to an inspection target;
detecting second light reflected by the inspection target;
generating a first spectrum using information about the second light;
generating a second spectrum by filtering the first spectrum;
comparing the second spectrum to a reference spectrum to generate a comparison result;
determining a first calibration parameter and a first calibration value thereof using the comparison result and a calibration library; and
calibrating a hardware of the substrate inspection apparatus using the first calibration parameter and the first calibration value;
forming a first material layer on a substrate; and
inspecting the first material layer using the calibrated substrate inspection apparatus,
wherein the calibration library comprises an entry of a relationship between the comparison result, and the first calibration parameter and the first calibration value,
the comparison result comprises a horizontal fluctuation of the second spectrum from the reference spectrum, a shift of the second spectrum from the reference spectrum, an offset of the second spectrum from the reference spectrum or a vertical fluctuation of the second spectrum from the reference spectrum, and
the first calibration parameter is associated with hardware of the substrate inspection apparatus in the calibration library.

21. The method of claim 20,
wherein the hardware includes a polarizer, a grating and a stage, and
wherein the first calibration parameter comprises a tilt angle of the polarizer, a tilt angle of the grating, a height of the stage, or an incident angle of the first light.

22-27. (canceled)
